(19) United States
(12) Patent Application Publication
(10) Pub. No.: US 2010/0207652 A1
(43) Pub. Date: Aug. 19, 2010

(54) METHOD FOR WAFER TEST AND PROBE CARD FOR THE SAME

(75) Inventors: In Buhm Chung, Seoul (KR); Byung Chang Song, Gyunggi-do (KR); Dong Il Kim, Gyunggi-do (KR)

Correspondence Address: HEAD, JOHNSON & KACHIGIAN, 228 W 17TH PLACE, TULSA, OK, 74119, US

(73) Assignee: Amst Co., Ltd.

(21) Appl. No.: 12/734,049

(22) PCT Filed: Oct. 8, 2008
(86) PCT No.: PCT/KR2008/005900

§ 371 Date: Apr. 6, 2010

(30) Foreign Application Priority Data
Oct. 8, 2007 (KR) 10-2007-0100771
Sep. 12, 2008 (KR) 10-2008-0090110

(51) Int. Cl. G01R 31/02

(52) U.S. Cl. 324/754

(57) ABSTRACT

A method of testing a wafer capable of minimizing the asymmetrical thermal deformation of a probe card when a wafer is tested using a probe card and of minimizing the number of times of tests to effectively test a large area wafer and a probe card for the same is presented. For the wafer test method for testing semiconductor chips on a wafer using a probe card, the method includes creating virtual repeating units corresponding to N semiconductor chips, wherein the N is natural number larger than or equal to 2, arranging the plurality of repeating units on the wafer and moving the probe card or the wafer N times and testing the semiconductor chips on a wafer, wherein the semiconductor chips in the repeating units are sequentially tested one by one per each touchdown. Also, the probe cards to realize above mentioned method have been described.

### TECHNICAL FIELD

The following descriptions relate to a method of testing a wafer and a probe card for the same, and more particularly, to a method of testing a wafer capable of minimizing the asymmetrical thermal deformation of a probe card during wafer testing using a probe card and of minimizing the number of touchdown by the probe card so as to effectively test a large area wafer and a probe card for the same.

### BACKGROUND ART

Generally, a semiconductor manufacturing process is largely divided into a front-end process and a back-end process. The front-end process, which is a fabrication process, is a process for forming an integrated circuit pattern on a wafer. The back-end process, which is an assembly process, is a process for forming an integrated circuit package by dividing the wafer into a plurality of chips, connecting a conductive lead or ball to each chip so as to provide electrical path to external devices and then molding the chips with epoxy.

Before performing the assembly process, an electrical die sorting (EDS) process of examining the electrical characteristics of the respective chips is performed. In the EDS process, among the chips that constitute the wafer, defective chips are discriminated so that repairable chips are repaired and irreparable chips are removed to save the time and cost spent in the following assembly process.

The EDS process is performed by a probe station. A probe station 100 commonly includes a wafer chuck 101 on which a wafer 102 to be tested is settled and a test head 103 including a probe card as illustrated in FIG. 1. A plurality of probes is provided on the probe card and the probes are electrically connected to the pads provided on the respective chips of the wafer to determine whether the corresponding chip is defective or not.

As the semiconductor technology develops, in order to save cost and to improve productivity, a larger number of chips are formed on a single wafer.

As described above, the larger wafer size means that the number of semiconductor chips to be tested at once in the EDS process of performing a test in units of wafers can be increased. Therefore, the number of probes provided on the probe card will be increased.

However, it is difficult to manufacture a probe card having the size corresponding to the large area wafer with enough probes so that all of the semiconductor chips on the wafer may be tested at once. In addition, there is a limitation on the capacity of a tester for processing the electrical signals transmitted to and received from the semiconductor chips on the wafer through the probe card.

In consideration of the above problems, in the related art, a method is selected in which a region to be tested in the large area wafer is divided into a plurality of unit regions and the regions are sequentially tested. For example, as illustrated in FIGS. 2 and 3, the wafer is divided into six regions, TD1 to TD6, or four regions, TD1 to TD4, and touchdown (TD) is sequentially performed from the region TD1 to the region TD4 or TD6 to test whole wafer. At this time, the probes are formed on the probe card in the area corresponding to one unit region. Here, the touchdown means that the probe card is contacting the wafer so that the probes on the probe card contact the pads of the semiconductor chips on the wafer.

As described above, in the existing wafer test method, the large area wafer may be tested using a smaller probe card. However, because the test is performed a plurality of times commonly at a high temperature such as above 85° C., the probe card is exposed to thermal deformation. As illustrated in FIGS. 2 and 3, since each touchdown area such as TD1 and TD2 are of different shape, the thermally contacted parts of the probe card to the wafer are different when sequentially testing from the first touchdown to the last touchdown. The consequential result is that the corresponding probe card may be thermally deformed asymmetrically during each touchdown. The thermal deformation can deteriorate the degree of flatness and the degree of alignment precision of the probe card, which can cause in the unstable contact between the probe card and the wafer, resulting in the unreliable test result. In addition, there exist a large number of probes that do not participate in the test when the respective regions are tested, resulting in the decline of the test resource usage efficiency.

### DISCLOSURE OF INVENTION

### Technical Problem

In an effort to solve the above-described problems associated with the related art, the following description relates a method of testing a wafer capable of minimizing the asymmetrical thermal deformation of a probe card when a wafer is tested using a probe card and of minimizing the number of times of tests to effectively test a large area wafer and a probe card for the same.

### Technical Solution

In this aspect, a wafer test method for testing semiconductor chips on a wafer using a probe card is provided. In this wafer test method, virtual repeating units corresponding to N (N is a natural number no less than 2) semiconductor chips are created so that the plurality of repeating units covers all the chips on the wafer, and the probe card or the wafer is moved N times and performs touchdown after each movement for the semiconductor chips testing.

On the probe card, probes are formed on the probe card only in a region corresponding to one semiconductor chip among the N semiconductor chips that constitute the repeating unit. In addition, when the probe card or the wafer is moved N times so that every semiconductor chips in the repeating unit are tested, a movement distance can correspond to the size of the semiconductor chip. All of the chips on the wafer may be tested by touching down the probe card N times.

When N is a prime number, the N semiconductor chips that constitute the repeating unit can be arranged in a row or a column. And, when N is a composite number, the N semiconductor chips that constitute the repeating unit can be arranged in a matrix (a×b) having a rows and b columns, where a and b are divisors of N including 1 and N.

In the probe card for testing the semiconductor chips on the wafer disclosed herein, when the repeating units each consisting of N (N is a natural number no less than 2) semiconductor chips are arranged on the wafer, the probes on the probe card are formed only in the regions corresponding to one semiconductor chip among the N semiconductor chips that constitute the repeating unit. At this time, the semiconductor chip corresponding to the region in which the probe is formed in the probe card may be in the same position in all of the repeating units.

In another aspect, there is provided a probe card, comprising a circuit board and a probe head body that are sequentially stacked, a plurality of unit probe modules arranged with intervals from each other on the probe head body, and one or a plurality of sub-board electrically connected to the unit probe modules provided on the probe head body and adjacent to the unit probe modules.

The unit probe modules can have a size corresponding to the size of the semiconductor chips or a size of from about 20% to 500% of the size of the semiconductor chips. At this time, the unit probe module may comprise a probe module body settled on the upper surface of the probe head body, probes provided on the upper surface of the probe module body, and electrically conductive path can be provided on the upper surface of the probe module body to be electrically connected to the probes, and a pad can be created at one end of electrically conductive path.

In addition, when virtual repeating units corresponding to N (N is a natural number no less than 2) semiconductor chips are created so that the plurality of repeating units covers all the chips on the wafer, the unit probe module on the probe card may be formed only in the regions corresponding to one semiconductor chip among the N semiconductor chips that constitute the repeating unit.

A vertical aperture is provided in the probe head body, and an interconnector can be inserted into the vertical aperture and the sub-board may be electrically connected to the circuit board by way of the interconnector. Here, the unit probe module may be electrically connected to the sub-board by wire bonding or through a flexible printed circuit board (FPCB). One or a plurality of unit probe modules may be connected to one side of the sub-board.

On the upper surface of the probe head body where the probe module and the sub-board are provided, the height of a region where the probe modules are placed may be different from the height of a region where the sub-boards are placed.

A stiffener plate may be further provided on the rear surface of the circuit board. A plurality of apertures that thoroughly penetrate the stiffener plate and the circuit board and partially penetrate the probe head body may be provided and the apertures formed in the probe head body, the circuit board, and the stiffener plate may be positioned in corresponding positions. In addition, screws that adjust planarity of the probes on the probe module may be inserted in the apertures and utilized. Elastic body with spring properties may be used with the planarity adjusting screws, and the elastic bodies may be positioned between the circuit board and the probe head body.

A plurality of apertures may be provided in the corresponding positions of the sub-board, the interconnector, the circuit board, and the stiffener plate and combining screws that combine some or all above components may be provided in the apertures. Female screws may be provided on the lower surface of the sub-board, apertures may be provided in the interconnector, the circuit board, and the stiffener plate, and male screws are provided in the apertures so that the male screws are combined with the female screws.

The area of the sub-board may correspond to the area of the probe head body. In addition, a plurality of sub-boards may be provided on the probe head body.

N may be a natural number between 2 and 50.

### Advantageous Effects

The wafer test method and the probe card for the same disclosed herein provide the following effects.

By performing a plural number of tests using the probes positioned relatively uniformly throughout the entire surface of the probe card so that it is possible to prevent or minimize the probe card from being thermally deformed asymmetrically. Since the number of probes that do not participate in the test at each touch down is smaller than in an existing test method, it is possible to reduce the number of tests while utilizing same amount of test resources, hence resulting in improved productivity of testing processes and in effective test of large area wafers.

### BRIEF DESCRIPTION OF THE DRAWINGS

Description will now be made in detail with reference to certain example embodiments illustrated in the accompanying drawings which are given hereinbelow by way of illustration only and thus are not limitative, wherein:

FIG. 1 illustrates the structure of a probe station;

FIGS. 2 and 3 illustrate a method of testing a wafer according to a related art; and

FIG. 4 illustrates a method of testing a wafer according to an embodiment disclosed herein;

FIG. 5 is a plan view illustrating the repeating units of wafers according to various embodiments disclosed herein;

FIG. 6 is a perspective view of a probe card according to an embodiment disclosed herein;

FIGS. 7 to 14 illustrate probe cards to which the unit test elements of FIGS. 5A to 5H are applied;

FIG. 15 is a plan view of a probe card according to an embodiment disclosed herein;

FIG. 16 is a sectional view taken along the line A-A of FIG. 15;

FIG. 17 is a perspective view of the enlargement of the probe card according to an embodiment disclosed herein; and

FIG. 18 illustrates a method of testing a wafer by dividing the wafer into four regions according to a related art.

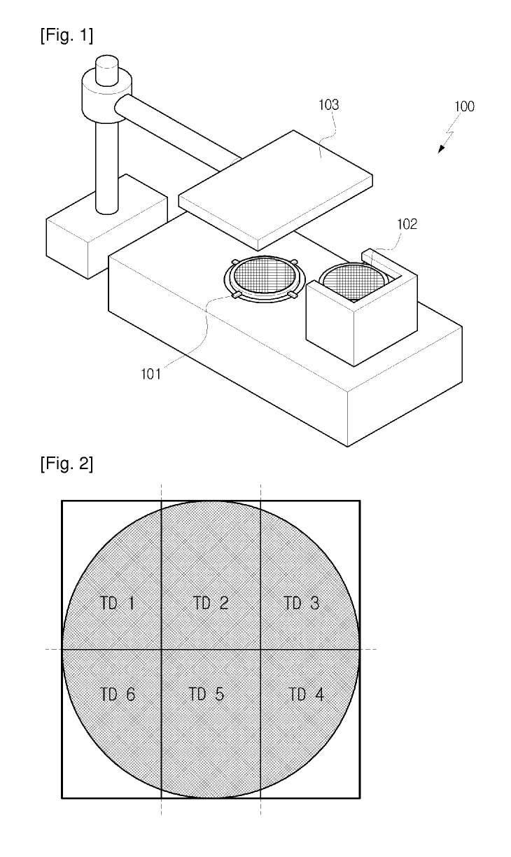

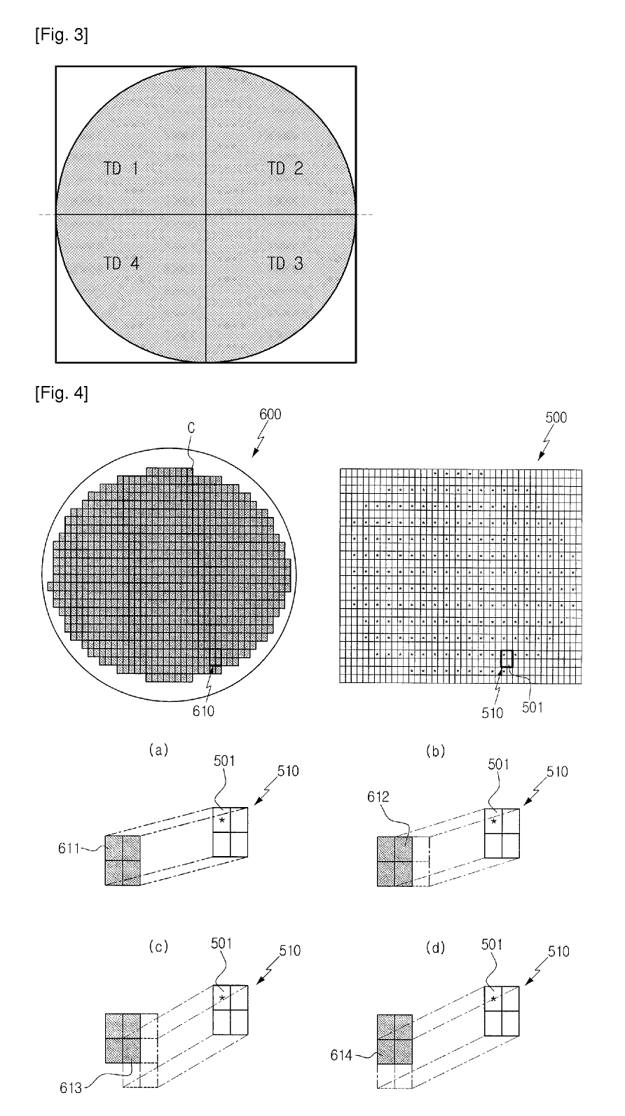

It should be understood that the appended drawings are not necessarily to scale, presenting a somewhat simplified representation of various preferred features illustrative of the method and probe card disclosed herein. The specific design features disclosed herein, including, for example, specific dimensions, orientations, locations, and shapes will be determined in part by the particular intended application and use environment.

In the figures, reference numbers refer to the same or equivalent parts throughout the figures.

### BEST MODE FOR CARRYING OUT THE INVENTION

Hereinafter, reference will now be made in detail to various embodiments, examples of which are illustrated in the accompanying drawings and described below. While description will be made in conjunction with example embodiments, it will be understood that the present description is not intended to be limitative.

### Mode for the Invention

Hereinafter, a method of testing a wafer and a probe card for the same according to an embodiment will be described in detail with reference to the drawings.

In order to realize the wafer test method disclosed herein, first, the concept of repeating units is applied to the semiconductor chips of a wafer to be tested. A plurality of semiconductor chips is provided on the wafer. The semiconductor chips are defined as a set of the repeating units and the repeating units are defined as a plurality of N adjacent semiconductor chips. N is a natural number no less than 2, for example, a natural number between 2 and 50. For example, in FIG. 4, the semiconductor chips C of the wafer 600 may be defined as a set of repeating units 610 consisting of four semiconductor chips C. At this time, neighboring repeating units may share some chips. For example, in defining a first repeating unit and a second repeating unit on a wafer, the semiconductor chips that belong to the first repeating unit may be all different from the semiconductor chips that belong to the second repeating unit or more than one of the semiconductor chips may be included in both of the repeating unit.

As described above, in the state where the repeating units are defined, in the wafer test method disclosed herein, the semiconductor chips in the repeating unit are sequentially touched down to be tested so that all of the semiconductor chips on the wafer may be tested.

As described above, since the semiconductor chips on the wafer are the set of the repeating units, it is noted that, when all of the semiconductor chips in the corresponding repeating unit are sequentially tested based on one repeating unit, all of the semiconductor chips on the wafer are tested. At this time, the repeating units are not arranged only on the wafer but may be arranged to cover the entire wafer. That is, part of the repeating units may be positioned outside the wafer.

The semiconductor chips on the wafer are tested using the probe card. As the semiconductor chips on the wafer are defined as the set of the repeating units and the semiconductor chips in the repeating units are sequentially tested, the concept of the repeating units on wafer is also realized in the probe card. That is, the probe card may be defined as the set of the unit test elements. For example, FIG. 4 illustrates a unit test element 510 consisting of four unit cells 501.

The unit test elements are provided in the positions corresponding to the repeating units of the wafer. The unit test elements consist of 2 to 50 adjacent unit cells and the sizes of the unit cells correspond to the sizes of the semiconductor chips. In addition, the probes are formed only on one cell among the plurality of unit cells consisting of the unit test elements.

As described above, in the state where the repeating units of the wafer and the unit test elements of the probe card are defined, the unit cells in which the probes are formed are sequentially positioned in the positions corresponding to the semiconductor chips in the repeating units so that all of the semiconductor chips in all of the repeating units may be tested and that all of the semiconductor chips on the wafer may be tested. At this time, the unit cells in which the probes are formed are sequentially positioned to correspond to the semiconductor chips in the repeating units by moving the wafer or the probe card.

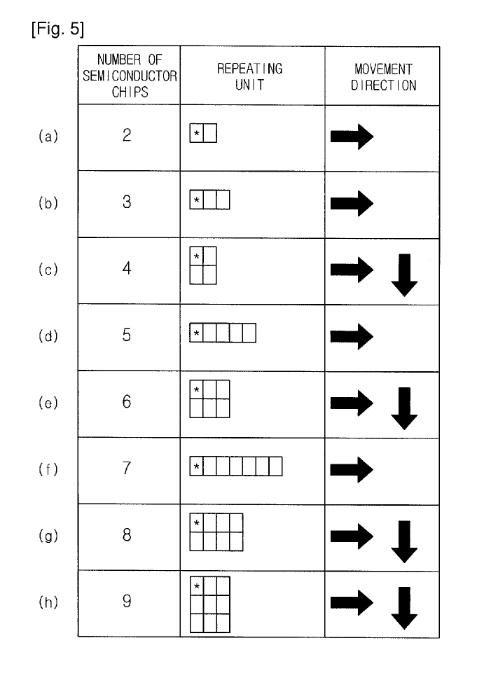

The repeating units may have various shapes as illustrated in FIG. 5. In FIGS. 5A to 5H, the repeating units are shown to consist of 2 to 9 semiconductor chips. At this time, when the numbers of semiconductor chips are 2, 3, 5, and 7, the plurality of semiconductor chips may be arranged in a row or a column. When the numbers N of semiconductor chips are 4, 6, 8, and 9, the plurality of semiconductor chips are arranged in a matrix having a rows and b columns (a×b, a and b are the divisors of the number of semiconductor chips including 1 and N). That is, when the number of semiconductor chips is a prime number, the semiconductor chips are arranged in a row or a column, and, when the number of semiconductor chips is a composite number, the semiconductor chips are arranged in a matrix having a plurality of rows and columns. As described above, in the case of the repeating units having the rows and the columns, the wafer is to be moved not only in the row direction but also in the column direction when the wafer is tested. For reference, as illustrated in FIG. 5, the asterisk mark (*) illustrates the unit cells in which the probes of the probe card are formed and the repeating units illustrated in FIGS. 5A to 5H correspond to the unit test elements of the probe card.

The embodiments of the repeating units consisting of the 2 to 9 semiconductor chips are illustrated in FIG. 5. However, the repeating units may consist of 10 or more semiconductor chips. The number of semiconductor chips may be properly determined in consideration of the efficiency of testing the wafer.

So far, the concept of the method of testing the wafer was described. Hereinafter, the wafer test method will be described. FIG. 4 illustrates that the repeating unit consists of four semiconductor chips, that is, that the unit test element consists of four unit cells.

First, the wafer 600 is aligned so that the unit cell where probes are formed among four unit cells 501 constituting the unit test element 510 corresponds to the first semiconductor chip 611 of the repeating unit 610. Then, the probe card 500 is touched down so that the probes of the corresponding unit cell 501 is connected to the pad of the first semiconductor chip 611 to test the wafer 600 (refer to FIG. 4A).

Then, in order to perform a second test, the wafer 600 is moved horizontally by the size of the unit cell 501, that is, by the size of one semiconductor chip. Therefore, the unit cell 501 in which the probe is formed is aligned to correspond to the second semiconductor chip 612 of the repeating unit 610. In such a state, when the probe card is touched down to connect the probe of the unit cell 501 to the pad of the second semiconductor chip 612, the second test is completed (refer to FIG. 4B). At this time, when the wafer is moved as much as the unit cell, the probe card 500 may be moved instead of moving the wafer 600.

Next, when the wafer 600 is moved vertically by the size of the unit cell 501 to be aligned in a third semiconductor chip 613 adjacent to the second semiconductor chip 612 and the probe of the corresponding unit cell 501 is connected to the pad of the third semiconductor chip 613 of the repeating unit 610, a third test is completed (refer to FIG. 4C).

Finally, when the wafer 600 is moved horizontally by the size of the unit cell 501 to be aligned in the fourth semiconductor chip 614 of the repeating unit 610 adjacent to the third semiconductor chip 613 and is touched down so that the probe of the corresponding unit cell 501 is connected to the pad of the fourth semiconductor chip 614, a fourth test is completed (refer to FIG. 4D)

As a plurality of repeating units 610 are created in the wafer 600 and the plurality of unit test elements 510 are provided in the positions corresponding to the repeating units 610 of the wafer 600 on the probe card, all of the semiconductor chips C provided on the wafer 600 may be tested through four times of tests.

So far, the wafer test method was described for the case in which the repeating unit consists of four adjacent semiconductor chips, that is, the case in which the unit test element consists of four adjacent unit cells as an example. However, the above-described wafer test method may be applied to any case in which the number of semiconductor chips of the repeating unit is a natural number between 2 and 50.

When the number of semiconductor chips that constitute the repeating unit is a composite number, since the corresponding repeating unit is in the matrix having rows and columns, in order to test all of the semiconductor chips of the wafer, the wafer is to be moved in the row directions and in the column directions like in the case where the repeating unit consists of four semiconductor chips. That is, when the number of semiconductor chips that constitute the repeating unit is 6, the repeating unit may be in a matrix of (2×3) or (3×2). And, when the number of semiconductor chips that constitute the repeating unit is 8, the repeating unit may be in a matrix of (2×4) or (4×2), and, when the number of semiconductor chips that constitute the repeating unit is 9, the repeating unit may be in a matrix of (3×3). As described above, in the case where the number of semiconductor chips is a composite number, as the wafer is moved in the column directions and in the row directions to test the wafer, all of the semiconductor chips on the wafer may be tested.

On the other hand, when the number of semiconductor chips that constitute the repeating unit is a prime number, the wafer may be moved only in one direction, for example, only in the row or column direction by the size of the semiconductor chip in accordance with the number of times of tests after testing the wafer by the first touch down to continuously test the wafer.

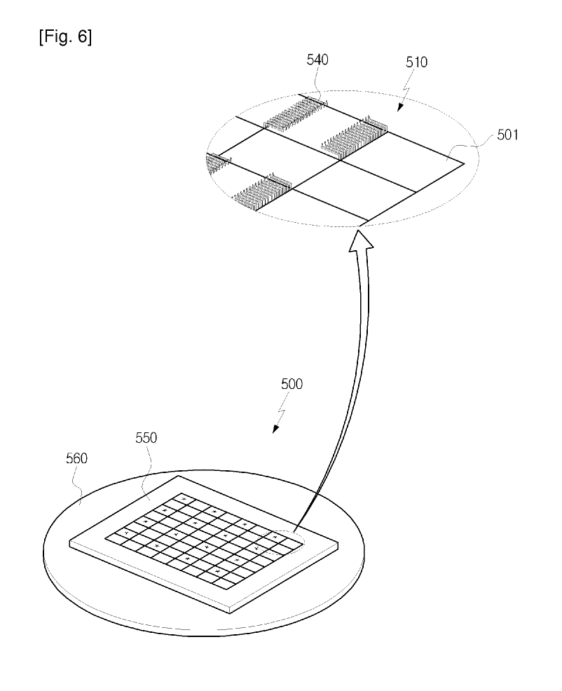

So far, the wafer test method according to an embodiment disclosed herein was described. Hereinafter, the probe card for realizing the wafer test method will be described. FIG. 6 is a perspective view of the probe card according to an embodiment disclosed herein.

First, as illustrated in FIG. 6, the plurality of unit test elements 510 are arranged in the probe card 500. The plurality of unit test elements 510 may be repeatedly arranged, but may be irregularly arranged in accordance with the arrangement of the semiconductor chips formed on the wafer.

The unit test element 510 may consist of a plurality of unit cells 501. The unit cell 501 may be the space corresponding to the size of the semiconductor chip provided on the wafer. The unit test elements 510 may be provided in the positions corresponding to the repeating units defined in the wafer.

In addition, in the unit test element 510, the probes are formed only in one unit cell among the plurality of unit cells 501 that constitute the unit test element 510 and the unit cell where the probes are formed is provided in the same position in all of the unit test elements. In FIG. 6, the unit cell marked with the asterisk (*) is the unit cell 501 where the probes are formed. In the actual probe card, the solid line that represents a unit cell region does not exist. However, in FIG. 4, the solid line is added for convenience sake in order to define the unit cell region.

As illustrated in FIG. 6, the probes 540 are formed on a probe head body 550 and the probe head body 550 is provided on a printed circuit board (PCB) 560. The probe 540 is electrically connected to the PCB 560. In FIG. 6, the probe head body 550 consists of one piece, however, it may consist of a plurality of pieces. Even though the probe head body 550 consists of a plurality of pieces, it is possible to provide a plurality of unit test elements in the similar way as was done on the one piece probe head body.

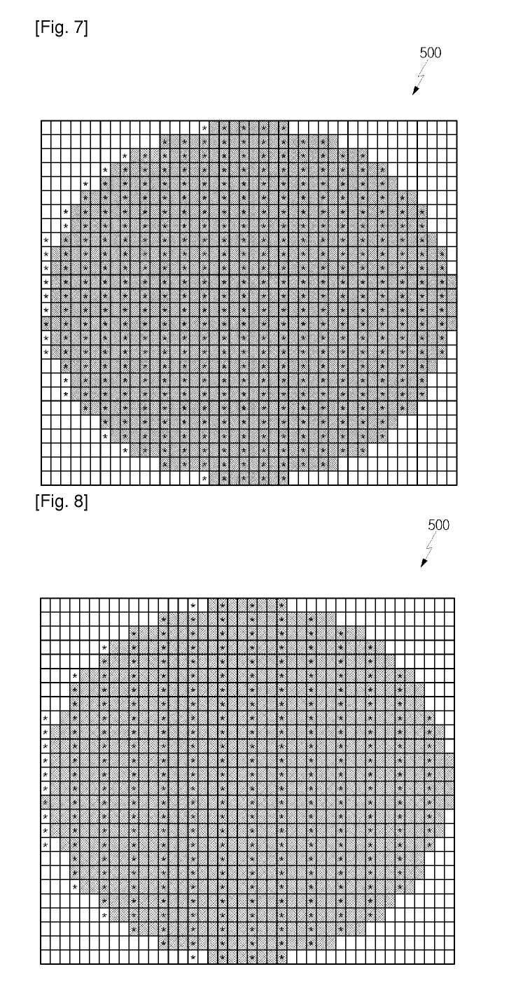

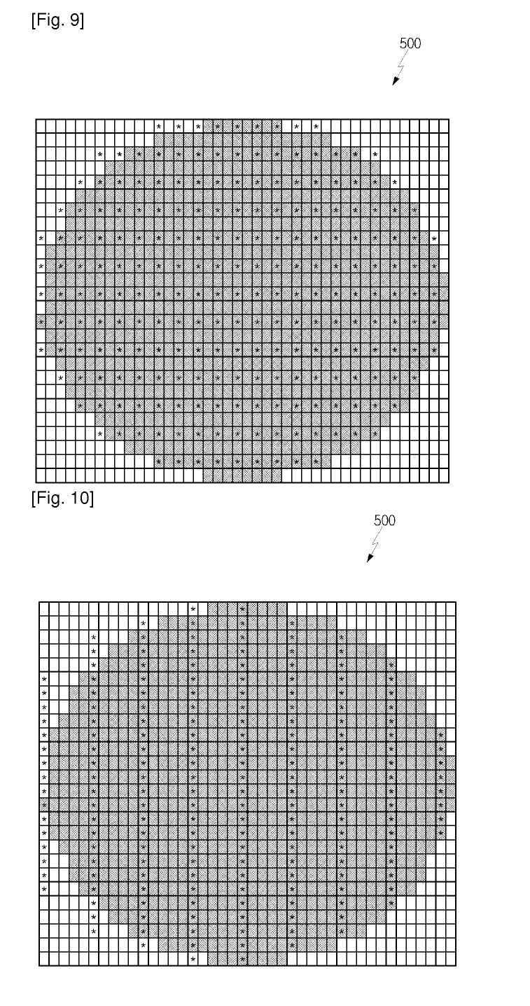

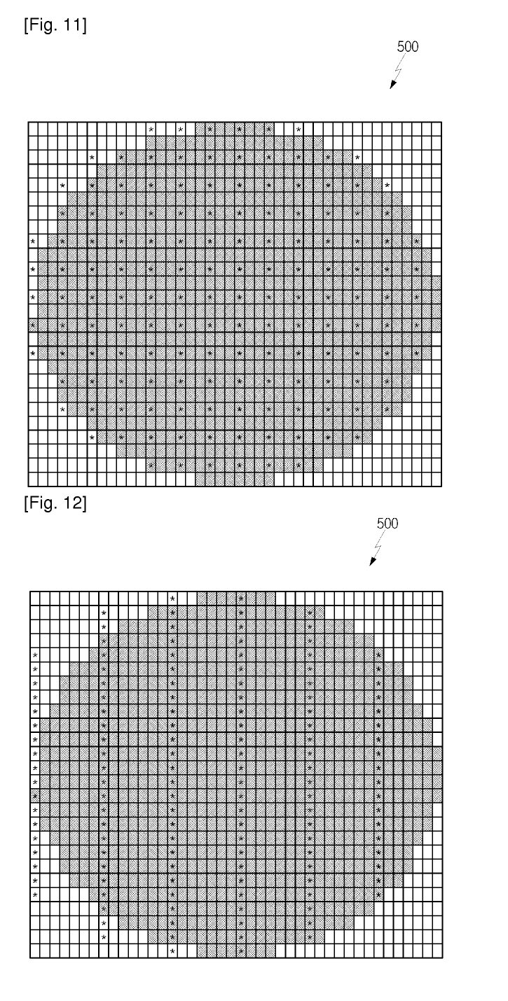

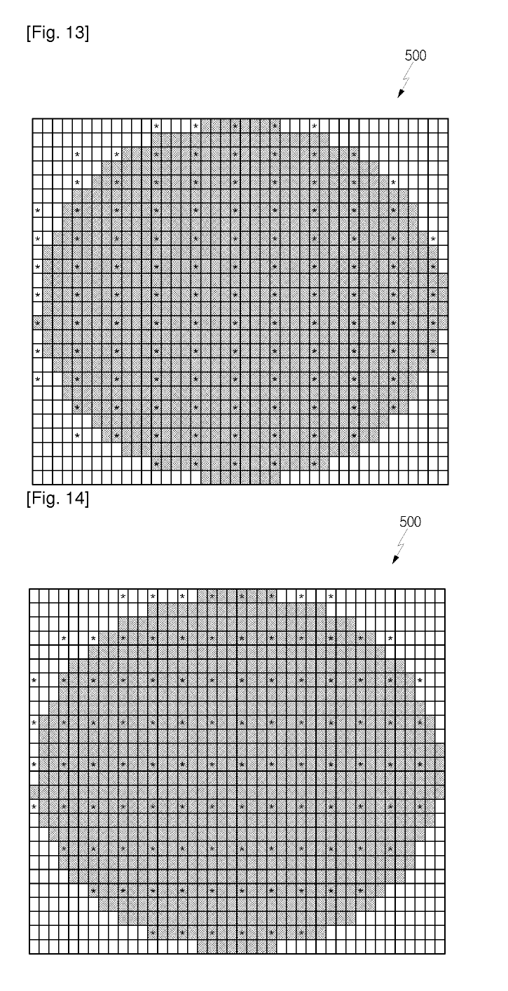

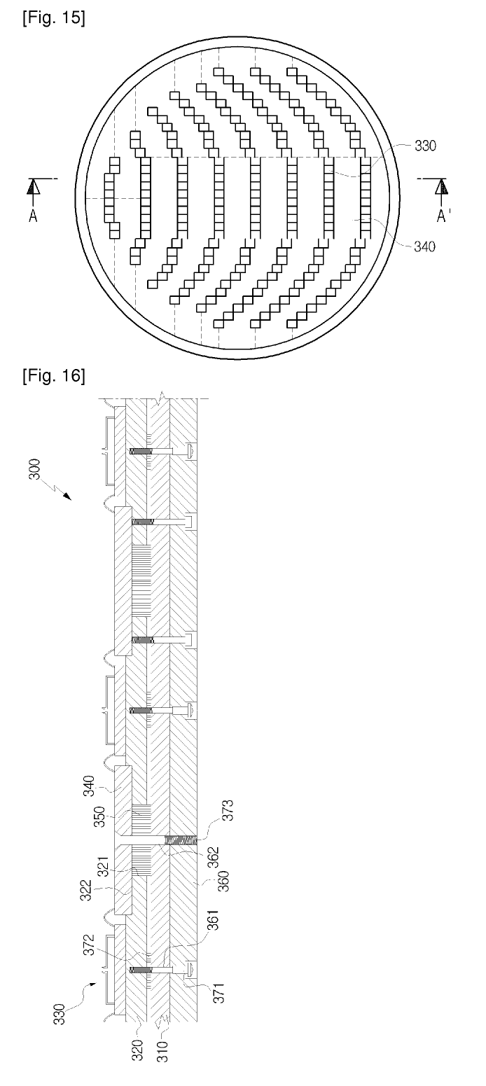

So far, the wafer test method and the probe card for realizing the same according to an embodiment were described. The embodiments of the repeating units consisting of the 2 to 9 semiconductor chips were described in FIG. 5. FIGS. 7 to 14 illustrate the probe cards, to be more precise, the probe head planes corresponding to the repeating units of FIGS. 5A to 5H. In FIGS. 7 to 14, the parts represented in gray are regions where the semiconductor chips are positioned on the wafer. In the actual probe cards, the gray parts and the solid lines that represent the unit cell regions do not exist.

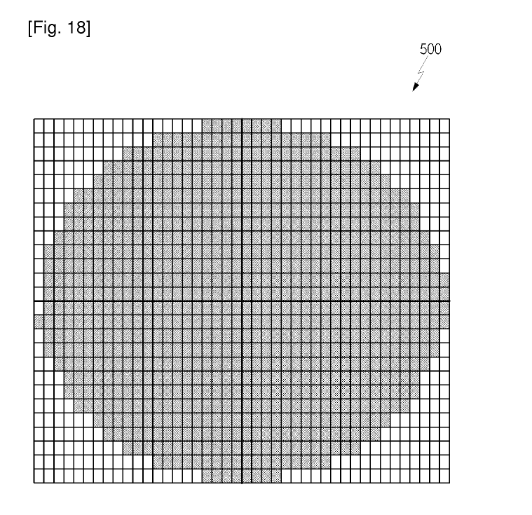

The probes may be uniformly arranged on the entire surface of the probe card so that it is possible to prevent the probe card from being thermally deformed asymmetrically. In addition, the number of times of touch downs may be minimized as compared to the related art. For example, in FIGS. 8 and 18, the gray parts are the same semiconductor wafer. In FIG. 18, the wafer is divided into four regions to touch down the wafer four times in the existing method. In FIG. 8, the repeating unit is set as three semiconductor chips and three touchdowns are needed to test the wafer. As a result, when compared to the existing method, in the test method disclosed herein, the number of times of touchdowns is reduced by one, which is significant since the resource of a tester for testing the semiconductor wafer is limited and effective usage of this resource is required. For example, when the resource of the tester can test 300 semiconductor chips on the wafer at once, in the existing method, a probe card to test the wafer as illustrated in FIG. 18 has 273 chips (13×21) testing capacity is needed and the wafer is touched down four times to test one entire wafer. On the other hand, in the embodiment disclosed herein, 288 repeating units consisting of three semiconductor chips are arranged on the same semiconductor wafer as illustrated in FIG. 8 and the wafer is touched down three times to test the entire wafer. This difference comes from a larger number of probes of the probe card which is not utilized during the process of testing the wafer in the existing method in comparison with this embodiment. In general, since time for testing the semiconductor chip by touching down the wafer once is almost the same, when the number of times of touch downs is reduced, the time spent in testing wafer may be decreased. For example, when the time for testing the semiconductor chip during one touchdown is ten minutes, then the time spent in testing one wafer is reduced from 40 minutes to 30 minutes so that productivity of testing the semiconductor wafer increased by more than 30%.

When the wafer is divided into 6, 8, or 12 regions to be tested in the conventional method, the new repeating unit may consist of 5, 7, and 10 semiconductor chips so that the number of times of touch downs may be reduced and that wafer test efficiency may be improved.

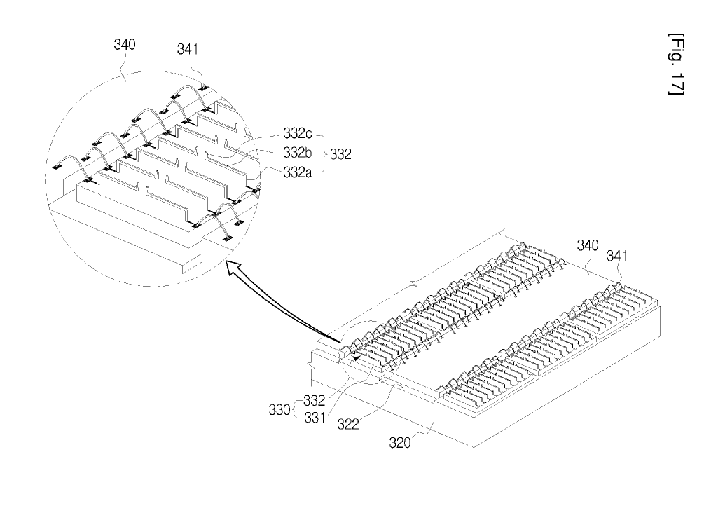

The probe card according to an embodiment was described above. A probe card according to another embodiment in which the probe head body and the structure thereof are specified will be described as follows. FIG. 15 is a plane view of the probe card according to an embodiment disclosed herein. FIG. 16 is a sectional view taken along the line A-A′ of FIG. 15.

As illustrated in FIGS. 15 and 16, the probe card according to another embodiment disclosed herein consists of a combination of a circuit board 310, a probe head body 320, a plurality of unit probe modules 330, and a sub-board 340, and has a structure in which the probe head body 320 is stacked on the circuit board 310 and the unit probe modules 330 are stacked on the probe head body 320. In addition, the sub-board 340 is provided between the unit probe modules 330 to electrically connect the unit probe modules 330 to the circuit board 310.

The components that constitute the probe card having the above structure will be described in detail as follows.

First, the unit probe modules 330 is made to contacts the semiconductor chips to be tested and transmits electric signals between the chips and the circuit board 310. In order to improve the manufacturing yield of the probe card, the unit probe modules 330 may have the size corresponding to the size of the semiconductor chips or the size of 20 to 500% of the size of the semiconductor chips. If the unit probe modules 330 have the size corresponding to the size of the semiconductor chips, the unit probe modules may correspond to the cells that constitute the unit test element 510.

The plurality of unit probe modules 330 are placed on the probe head body 320 and separated from each other by a predetermined distance and the sub-board 340 is provided between the unit probe modules 330 so that the distance between the unit probe modules 330 is correlated with the width of the sub-board 340.

The circuit board 310 receives the electric signals from the unit probe modules 330 through the sub-board 340, transmits the electric signals to an external tester, and transmits the electric signals applied from the external tester to the unit probe modules 330.

The probe head body 320 is mounted on the circuit board 310, has an area corresponding to the wafer to be tested, and may be formed of stainless steel, aluminum, Invar, Kovar, Nobinite, SKD11, alumina, glass or machinable ceramics. In addition, the probe head body 320 provides a space in which the plurality of unit probe modules 330 and the sub-board 340 are settled. As described above, the plurality of unit probe modules 330 are provided on the probe head body 320 to be separated from each other by a predetermined distance and the sub-board 340 is provided between the unit probe modules 330. The sub-board 340 and the unit probe modules 330 are electrically connected to each other by wire bonding or through a flexible printed circuit board (FPCB) 310. Here, the probe head body 320 and the sub-board 340 may be combined with each other through an adhesive such as epoxy.

An interconnector 350 is provided under the sub-board 340. In detail, a vertical aperture 321 is created in the probe head body 320 corresponding to the position in which the sub-board 340 is provided, the interconnector 350 is inserted in the vertical aperture 321, and the interconnector 350 is electrically connected to the circuit board 310. Therefore, the interconnector 350 is contacting the circuit board 310, the sub-board 340 is stacked on the interconnector 350, and the unit probe modules 330 are connected to the circuit board 310 by way of the sub-board 340 and the interconnector 350. Here, the interconnector 350 may be formed of a Pogo pin or pressure conductive rubber (PCR).

The height of the region where the sub-board 340 is placed may be different from the height of the region where the probe modules 330 are placed in order to compensate for the difference in the thickness of sub-board and the probe module and to control the height difference after attachment. Here, the vertical aperture 321 may be formed in the probe head body 320 by a drilling process, a wire discharge machining process, a laser process, or a micro sandblasting process.

So far, the components of the probe card according to another embodiment were described. Hereinafter, the structure of the unit probe modules 330 and the electric connection structure between the unit probe modules 330 and the sub-board 340 will be described.

First, as illustrated in FIG. 17, the unit probe module 330 consists of an insulating probe body 331 and probes 332 attached on the probe body 331. The probe 332 consists of a column 332a, a beam 332b and a tip 332c, and the tip 332c is the part which contacts the pad of the semiconductor chip to be tested. Metal lines 333 and pads 334 are provided on the probe body 331 for transmitting the electric signal between the semiconductor chip and the circuit board 310.

Next, the electric connection structure between the unit probe modules 330 and the sub-board 340 will be described. A bonding pad 341 is provided on the sub-board 340 and the bonding pad 341 of the sub-board 340 is electrically connected to the pad 334 of the unit probe module 330 by the wire bonding process. FIG. 17 shows one unit probe module 330 electrically connected to each side of the sub-board 340. However, one or a plurality of unit probe modules 330 may be connected to one side of the sub-board 340. For reference, the unit probe modules 330 may be electrically connected to the sub-board 340 through the FPCB 310 as well as by the wire bonding as described above.

The sub-board 340 may be formed of a multilayer ceramic circuit board 310 or may be formed of an impedance matched PCB 310 in order to improve signal integrity between the tester and the wafer to be tested. In addition, the sub-board 340 may be processed so that the plurality of sub-boards formed in accordance with the shape of the space between the unit probe modules 330 are placed on the probe head body or that single piece sub-board from which only the regions in which the unit probe modules 330 are formed are removed and having the area corresponding to the probe head body 320 can be formed.

The probe card according to another embodiment disclosed herein includes the circuit board 310, the probe head body 320, plurality of unit probe modules 330, the sub-board 340, the interconnector 350, and a stiffener plate 360 for physically supporting the components.

The stiffener plate 360 is placed on the rear surface of the circuit board 310 and physically combined with the probe head body 320, the sub-board 340, the interconnector 350, and the circuit board 310 to support the combined components. The stiffener plate 360 may have a structure in which one or more of stainless steel, aluminum, Invar, Korva, Nobinite, and SKD11 are combined with each other and stacked.

In addition, a plurality of apertures 361 is provided in the stiffener plate 360, the circuit board 310, and the probe head body 320. The apertures 361 formed in the stiffener plate 360, the circuit board 310, and the probe head body 320 are created in the corresponding positions. The apertures 361 thoroughly penetrate the stiffener plate 360 and the circuit board 310 and partially penetrate the probe head body 320 and screw threads for flat adjusting screws 371 to be described later are formed in the apertures 361.

The flat adjusting screws 371 are provided in the apertures 361 and the flat adjusting screws 371 pull the probe head body 320 toward the stiffener plate 360. Elastic bodies with spring properties 372 are used with the flat adjusting screws 371 and the corresponding elastic bodies 372 may be placed between the circuit board 310 and the probe head body 320. The elastic bodies 372 push the probe head body 320 from the stiffener plate 360. The flatness of the probe head may be controlled selectively and locally by way of the elastic bodies 372 and the flat adjusting screws 371 based on the stiffener plate 360.

So far, the physical combination through the stiffener plate 360 was described. In addition to the physical combination through the stiffener plate 360, a stable physical combination among the interconnector 350, the sub-board 340, and the circuit board 310 is required because stable electrical connection is necessary between the sub-board 340 and the circuit board 310 with the interconnector 350 interposed. Therefore, according to an embodiment, the plurality of apertures 361 are provided in the sub-board 340, the interconnector 350, the circuit board 310, and the stiffener plate 360 in the corresponding positions and combining screws 373 may be installed in the apertures 362.

In one embodiment, the apertures of the sub-board 340, the interconnector 350, and the circuit board 310 are thoroughly penetrated, the apertures of the stiffener plate 360 are partially penetrated, and the screw threads for the combining screws are formed in the apertures of the stiffener plate 360. According to another embodiment, after female screws are firmly attached to the lower surface of the sub-board 340 and apertures are formed in the probe head body 320, the interconnector 350, the circuit board 310, and the stiffener plate 360, the stiffener plate 360 may be combined with the female screws on the lower surface of the sub-board 340 using male screws.

### INDUSTRIAL APPLICABILITY

As described above, a plurality of tests may be performed using the probes uniformly provided on the entire surface of the probe card so that it is possible to prevent or minimize the probe card from being thermally deformed asymmetrically.

Further, since the number of probes that do not participate in the test per each touch down is smaller than in existing test methods, it is possible to reduce the number of times of tests, hence resulting in improvement of the productivity of testing processes and in efficient testing of large area wafers.

1. A wafer test method for testing semiconductor chips on a wafer using a probe card,
creating virtual repeating units corresponding to N semiconductor chips,
wherein the N is natural number larger than or equal to 2,
arranging the plurality of repeating units on the wafer, and
moving the probe card or the wafer N times and testing the semiconductor chips on a wafer, wherein the semiconductor chips in the repeating units are sequentially tested one by one through N touch downs.

2. The wafer test method as set forth in claim 1, wherein probes are formed on the probe card only in regions corresponding to one semiconductor chip among the N semiconductor chips that constitute the repeating unit.

3. The wafer test method as set forth in claim 1, wherein, when the probe card or the wafer is moved N times, every semiconductor chips in the repeating unit are tested, with a movement distance of the probe card or the wafer corresponds to the size of the semiconductor chip.

4. The wafer test method as set forth in claim 1, wherein all of the semiconductor chips on the wafer are tested by touching down the probe card N times.

5. The wafer test method as set forth in claim 1, wherein, when N is a prime number, the N semiconductor chips that constitute the repeating unit are arranged in a row or a column.

6. The wafer test method as set forth in claim 1, wherein, when N is a composite number, the N semiconductor chips that constitute the repeating unit are arranged in a matrix (a×b) having a rows and b column and the a and b are divisors of N.

7. The wafer test method as set forth in claim 1, wherein N is a natural number between 2 and 50.

8. A probe card for testing semiconductor chips on a wafer, comprising: probes contacting the semiconductor chips; and
a probe head on where the probes are arranged,wherein virtual repeating units corresponding to N semiconductor chips are created, wherein the N is a natural number larger than or equal to 2 and wherein, when the plurality of repeating units are provided on the wafer, the probes are formed only in the regions corresponding to one semiconductor chip among the N semiconductor chips that constitute the repeating unit.

9. The probe card as set forth in claim 8, wherein the semiconductor chips corresponding to the region on where the probes are formed in the probe card are in the same position in all of the repeating units.

10. The probe card as set forth in claim 8, wherein all of the semiconductor chips on the wafer are tested by touching down the probe card N times on the wafer.

11. The probe card as set forth in claim 8, wherein, when N is a prime number, the N semiconductor chips that constitute the repeating unit are arranged in a row or a column.

12. The probe card as set forth in claim 8, wherein, when N is a composite number, the N semiconductor chips that constitute the repeating unit are arranged in a matrix (a×b) having a rows and b column and a and b are divisors of N.

13. The probe card as set forth in claim 8, wherein N is a natural number between 2 and 50.

14. A probe card, comprising:
a circuit board and a probe head body that are sequentially stacked;
a plurality of unit probe modules are arranged with intervals from each other on the probe head body; and
at least one sub-boards electrically connected to the unit probe modules are provided on the probe head body and adjacent to the unit probe modules.

15. The probe card as set forth in claim 14, wherein the unit probe modules have a size corresponding to the size of the semiconductor chips.

16. The probe card as set forth in claim 14, wherein the unit probe modules have a size of 20 to 500% of the size of the semiconductor chips.

17. The probe card as set forth in claim 14, wherein the unit probe module comprises:
a probe module body attached on the upper surface of the probe head body;
probes attached on the upper surface of the probe module body; and
metal lines formed on the upper surface of the probe module body to be electrically connected to the probes; and
pads formed at one end of the metal lines.

18. The probe card as set forth in claim 14, wherein, when virtual repeating units corresponding to N semiconductor chips are created and when the plurality of repeating units are created on a wafer to be tested, the unit probe modules in the probe card are formed only in the regions corresponding to one semiconductor chip among the N semiconductor chips that constitute the repeating unit, wherein the N is a natural number larger than or equal to 2.

19. The probe card as set forth in claim 18, wherein, in the probe card, the semiconductor chips corresponding to the region in which the unit probe module is formed are in the same position in all of the repeating units.

20. The probe card as set forth in claim 18, wherein all of the chips on the wafer are tested by touching down the probe card N times on the wafer.

21. The probe card as set forth in claim 14, further comprising a vertical aperture provided in the probe head body of a region on which the sub-board is provided; and
an interconnector inserted in the vertical aperture;
wherein the sub-board is electrically connected to the circuit board through the interconnector.

22. The probe card as set forth in claim 14, wherein the unit probe module is electrically connected to the sub-board by wire bonding or through a flexible printed circuit board (FPCB).

23. The probe card as set forth in claim 14, wherein one or a plurality of unit probe modules are connected to one side of the sub-board.

24. The probe card as set forth in claim 14, wherein, on the upper surface of the probe head body where the probe module and the sub-board are provided, the height of the region on which the probe modules are attached is different from the height of the region on which the sub-boards are placed.

25. The probe card as set forth in claim 14, further comprising a stiffener plate on the rear surface of the circuit board.

26. The probe card as set forth in claim 25, further comprising a plurality of apertures thoroughly penetrating the stiffener plate and the circuit board and partially penetrating the probe head body,
wherein the apertures formed in each of the probe head body, the circuit board, and the stiffener plate are position in corresponding positions.

27. The probe card as set forth in claim 26, further comprising flat adjusting screws provided in each apertures.

28. The probe card as set forth in claim 27,
wherein the flat adjusting screws have elastic bodies with spring properties, and
wherein the elastic bodies are placed between the circuit board and the probe head body.

29. The probe card as set forth in claim 21, further comprising a stiffener plate provided on the rear surface of the circuit board;
a plurality of apertures are provided in the corresponding positions of the sub-board, the interconnector, the circuit board, and the stiffener plate; and
combining screws provided in the apertures.

30. The probe card as set forth in claim 21, further comprising a stiffener plate is provided on the rear surface of the circuit board;
female screws provided on the lower surface of the sub-board;
apertures provided through the interconnector, the circuit board, and the stiffener plate; and
male screws provided in the apertures, wherein the male screws are combined with the female screws.

31. The probe card as set forth in claim 14, wherein the sub-board is formed of a printed circuit board or a multilayer ceramic circuit board.

32. The probe card as set forth in claim 14, wherein the area of the sub-board corresponds to the area of the probe head body.

33. The probe card as set forth in claim 14, wherein a plurality of sub-boards are provided on the probe head body.

34. The probe card as set forth in claim 18, wherein N is a natural number between 2 and 50.
